(19) United States
(12) Patent Application Publication
(10) Pub. No.: US 2026/0245611 A1
(43) Pub. Date: Aug. 20, 2026

(54) MEMORY DEVICE WITH BIT LINE AND COMPLEMENTARY BIT LINE COUPLING SUPPRESSION STRUCTURE

(71) Applicant: SAMSUNG ELECTRONICS CO., LTD., Suwon-si (KR)

(72) Inventors: Duckyoung SEO, Suwon-si (KR); Kyu-Chang KANG, Suwon-si (KR); Kyeongtae NAM, Suwon-si (KR); Young Seok PARK, Suwon-si (KR); Younghun SEO, Suwon-si (KR); Jeonghyun LEE, Suwon-si (KR); Changyoung LEE, Suwon-si (KR); Kangsub JEONG, Suwon-si (KR)

(73) Assignee: SAMSUNG ELECTRONICS CO., LTD., Suwon-si (KR)

(21) Appl. No.: 19/541,944

(22) Filed: Feb. 17, 2026

(30) Foreign Application Priority Data
Feb. 17, 2025 (KR) 10-2025-0019958
Apr. 10, 2025 (KR) 10-2025-0046782

(51) Int. Cl. G11C 11/4091; G11C 11/4097

(52) U.S. Cl. CPC G11C 11/4091; G11C 11/4097

(57) ABSTRACT

A memory device includes a plurality of memory cell arrays having bit lines extending in a first direction and complementary bit lines extending in the first direction and corresponding to the bit lines. A bit line sense amplifier array is disposed relative to the memory cell arrays in a second direction intersecting the first direction and at least partly overlaps the memory cell arrays. The bit line sense amplifier array is connected to selected bit lines and complementary bit lines through cell wafer metal wirings and bonding structures, thereby reducing coupling effects and enabling reliable sensing operation.

### CROSS-REFERENCE TO RELATED APPLICATION

This application claims priority to and the benefit of Korean Patent Application No. 10-2025-0019958 filed with the Korean Intellectual Property Office on February 17, 2025, and Application No. 10-2025-0046782 filed with the Korean Intellectual Property Office on April 10, 2025, the entire contents of which are incorporated herein by reference.

### BACKGROUND

### Field

The present disclosure relates to a semiconductor memory device.

### Description of the Related Art

Volatile memory devices, such as dynamic random access memory (DRAM), store data by storing charge in the capacitive load of memory cells, and read data by determining the charge stored in the capacitive load.

A bit line sense amplifier may be connected to the memory cell to sense data stored in the memory cell. A bit line sense amplifier may detect and amplify the voltage level difference between a bit line and a complementary bit line, which is determined by data stored in a memory cell.

Meanwhile, in conventional DRAM structures, coupling may occur between adjacent bit lines and between adjacent complementary bit lines, which may cause problems in which the bit line sense amplifier cannot accurately detect voltage level differences. To solve this, additional shield structures may be placed between adjacent bit lines and between adjacent complementary bit lines, but even in this case, there are design and process difficulty and cost issues.

### SUMMARY

The present disclosure attempts to provide a memory device capable of suppressing coupling occurrence between bit lines and complementary bit lines.

According to one embodiment of the present disclosure for solving these technical problems, a memory device may include a plurality of memory cell arrays including a plurality of bit lines extending in a first direction, and a plurality of complementary bit lines extending in the first direction and corresponding to the plurality of bit lines, and a bit line sense amplifier array arranged on the plurality of memory cell arrays in a second direction intersecting the first direction, overlapped at least partly with the plurality of memory cell arrays, and connected to a subset of bit lines included in the plurality of bit lines through a cell wafer metal wiring connected to the subset of the bit lines, and connected to a subset of the complementary bit lines included in the plurality of the complementary bit lines through a cell wafer metal wiring connected to the subset of the complementary bit lines.

A memory device according to one embodiment may include a first substrate including a plurality of bit lines extending in a first direction, a plurality of complementary bit lines extending in the first direction and corresponding to the plurality of bit lines, a plurality of cell wafer metal wirings formed above the plurality of bit lines and the plurality of complementary bit lines along a second direction intersecting the first direction and extending in the first direction, a plurality of contacts formed in the second direction and connecting a subset of the bit lines included in the plurality of bit lines and a subset of the complementary bit lines included in the plurality of complementary bit lines to the plurality of cell wafer metal wirings, and a plurality of bonding pads formed in the second direction and connected to the plurality of cell wafer metal wirings, and a second substrate including a bit line sense amplifier array arranged above the first substrate along the second direction and connected to the plurality of bonding pads.

A memory device according to one embodiment may include a plurality of first bit lines extending in a first direction, a plurality of first complementary bit lines extending in the first direction and corresponding to the plurality of first bit lines, a plurality of second bit lines extending in the first direction, and alternately arranged with the plurality of first bit lines or the plurality of first complementary bit lines along a second direction intersecting the first direction, a plurality of second complementary bit lines extending in the first direction, and alternately arranged with the plurality of first bit lines or the plurality of first complementary bit lines along the second direction, a plurality of cell wafer metal wirings arranged above the first bit line, the first complementary bit line, the second bit line, and the second complementary bit line along a third direction intersecting the first direction and the second direction, and connecting the plurality of first bit lines, the plurality of first complementary bit lines, the plurality of second bit lines, and the plurality of second complementary bit lines through a plurality of contacts, and a plurality of bonding pads arranged above the plurality of cell wafer metal wirings along the third direction, and connecting the plurality of cell wafer metal wirings to a plurality of bit line sense amplifier arrays.

### BRIEF DESCRIPTION OF THE DRAWINGS

FIG. 1 is a block diagram illustrating a memory device according to one embodiment of the present disclosure.

FIG. 2 is a perspective view illustrating a memory device according to one embodiment of the present disclosure.

FIG. 3 is a drawing illustrating a memory device according to one embodiment of the present disclosure illustrated in FIG. 2.

FIG. 4 is a perspective view illustrating a memory device according to one embodiment of the present disclosure.

FIG. 5 is a drawing illustrating a memory device according to one embodiment of the present disclosure illustrated in FIG. 4.

FIG. 6 is a drawing illustrating a memory device according to one embodiment of the present disclosure.

FIG. 7 is a drawing illustrating a memory device according to one embodiment of the present disclosure.

FIG. 8 is a drawing illustrating a memory device according to one embodiment of the present disclosure.

FIG. 9 is a perspective view schematically illustrating a memory device according to one embodiment of the present disclosure.

FIG. 10 is a cross-sectional view along one direction of a memory device according to one embodiment of the present disclosure.

FIG. 11 is a perspective view schematically illustrating a memory device according to one embodiment of the present disclosure.

FIG. 12 is a cross-sectional view along one direction of a memory device according to one embodiment of the present disclosure.

FIG. 13 is a drawing illustrating a memory device according to one embodiment of the present disclosure.

FIG. 14 is a drawing illustrating a memory device according to one embodiment of the present disclosure.

FIG. 15 is a perspective view schematically illustrating a memory device according to one embodiment of the present disclosure.

FIG. 16 is a cross-sectional view along one direction of a memory device according to one embodiment of the present disclosure.

FIG. 17 is a perspective view schematically illustrating a memory device according to one embodiment of the present disclosure.

FIG. 18 is a cross-sectional view along one direction of a memory device according to one embodiment of the present disclosure.

FIG. 19 is a diagram illustrating a bit line sense amplifier included in a memory device according to one embodiment of the present disclosure.

FIG. 20 is a block diagram illustrating a computing device according to one embodiment of the present disclosure.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as "a", "an", or "single" are used. Terms including an ordinal number, such as first and second, are used for describing various constituent elements, but the constituent elements are not limited by the terms. These terms are used only to discriminate one constituent element from other constituent elements.

Hereinafter, the present disclosure will be described in more detail through examples. These examples are just for illustrating the present disclosure, and the right protection scope of the present disclosure is not limited by the examples.

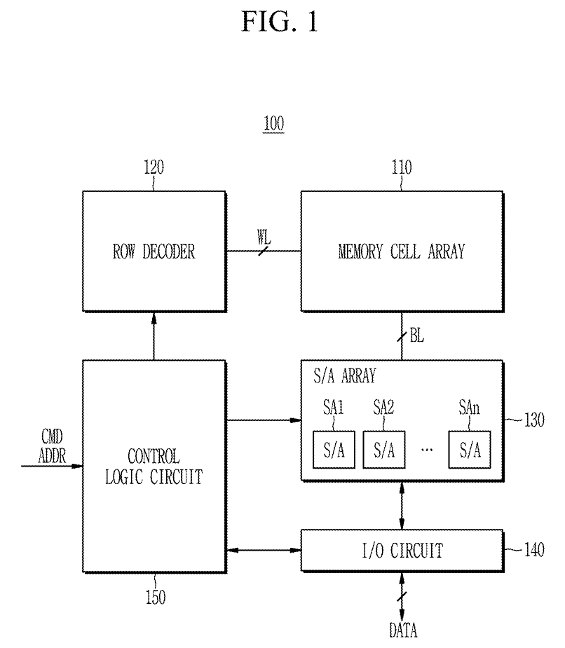

FIG. 1 is a block diagram illustrating a memory device according to one embodiment of the present disclosure.

Referring to FIG. 1, a memory device 100 may include a memory cell array 110, a row decoder 120, a bit line sense amplifier array 130, an input/output (I/O) circuit 140, and a control logic circuit 150.

The memory cell array 110 may include a plurality of memory cells arranged in the row direction and the column direction. A plurality of memory cells may be connected to a plurality of word lines WL extending in the row direction and a plurality of bit lines BL extending in the column direction.

For brief explanation, an embodiment in which each of the plurality of memory cells is a dynamic random access memory (DRAM) cell will be described below as a representative example. However, the embodiment is not limited thereto, and each of the plurality of memory cells may be any type of volatile memory cell, such as a static random access memory SRAM cell, or any type of non-volatile memory cell, such as a flash memory cell. That is, the scope of the present disclosure is not limited to the type of memory device 100.

A row decoder 120 may control a plurality of word lines WL. For example, the row decoder 120 may activate a subset of the plurality of word lines WL based on an address ADDR provided to the control logic circuit 150.

The bit line sense amplifier array 130 may include a plurality of bit line sense amplifiers S/A. For example, the bit line sense amplifier array 130 may include first to n-th bit line sense amplifiers SA1 to SAn.

Each of the plurality of bit line sense amplifiers SA1 to SAn may be connected to the plurality of bit lines BL. For example, each of the plurality of bit line sense amplifiers SA1 to SAn may be connected to a bit line and a complementary bit line. Each of the plurality of bit line sense amplifiers SA1 to SAn may detect and amplify a change in the voltage level of a connected bit line BL based on a voltage level difference between the connected bit line and the complementary bit line.

The input/output circuit 140 may output data corresponding to a change in the voltage level of a bit line BL amplified by the bit line sense amplifier array 130 to the outside or receive data from the outside.

The control logic circuit 150 may receive a command CMD and an address ADDR. The control logic circuit 150 may control all operations of the memory device 100 based on a command CMD and an address ADDR.

In one embodiment of the present disclosure, the control logic circuit 150 may provide a plurality of control signals to the bit line sense amplifier array 130. For example, the control logic circuit 150 may provide a plurality of control signals to the bit line sense amplifier array 130 to control the operation of each of the plurality of bit line sense amplifiers S/A.

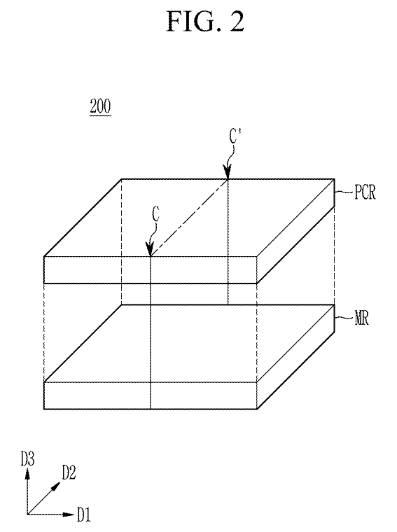

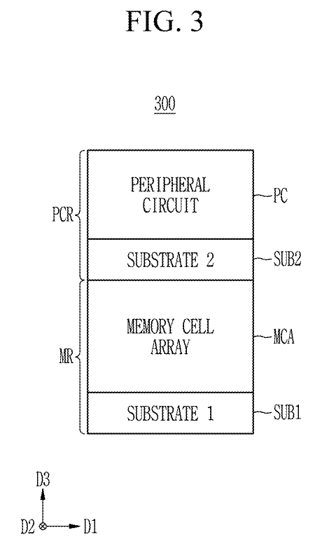

FIG. 2 is a perspective view illustrating a memory device according to one embodiment of the present disclosure. FIG. 3 is a drawing illustrating a memory device according to one embodiment of the present disclosure illustrated in FIG. 2.

Referring to FIG. 2, a memory device 200 may include a memory region MR and a peripheral circuit region PCR. The peripheral circuit region PCR may be three-dimensionally stacked on the memory region MR along the third direction D3. That is, the memory device 200 may have a Peripheral on Cell (PoC) structure.

Specifically, referring to FIG. 3, the memory region MR of the memory device 300 may include a first substrate SUB1 and a memory cell array MCA (memory cell array 110 illustrated in FIG. 1) formed on the first substrate SUB1. The peripheral circuit region PCR may include a second substrate SUB2 and peripheral circuit PC (a row decoder 120, a bit line sense amplifier array 130, an input/output circuit 140, and a control logic circuit 150 illustrated in FIG. 1) formed on the second substrate SUB2.

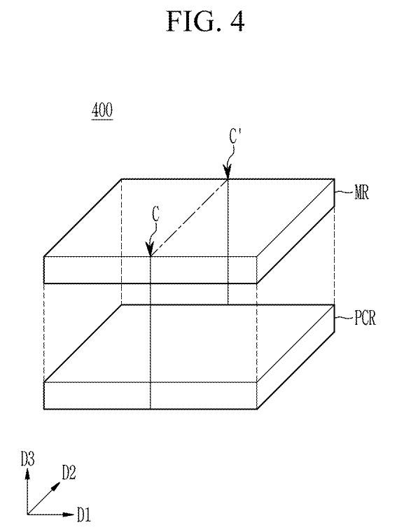

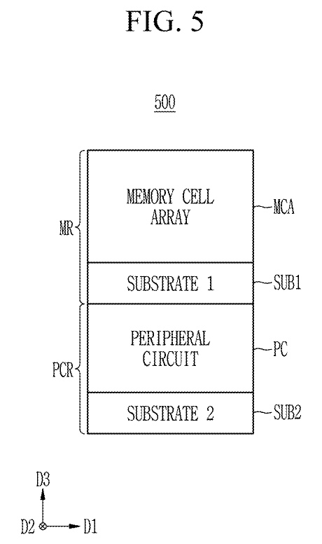

FIG. 4 is a perspective view illustrating a memory device according to one embodiment of the present disclosure. FIG. 5 is a drawing illustrating a memory device according to one embodiment of the present disclosure illustrated in FIG. 4.

Referring to FIG. 4, the memory device 400 may include a peripheral circuit region PCR and a memory region MR. The memory region MR may be three-dimensionally stacked on the peripheral circuit region PCR along the third direction D3. That is, the memory device 400 may have a Cell on Peripheral (CoP) structure.

Specifically, referring to FIG. 5, the peripheral circuit region PCR of the memory device 500 may include a second substrate SUB2 and a peripheral circuit PC (a row decoder 120, a bit line sense amplifier array 130, an input/output circuit 140, and a control logic circuit 150 illustrated in FIG. 1) formed on the second substrate SUB2. The memory region MR may include a first substrate SUB1 and a memory cell array MCA (memory cell array 110 illustrated in FIG. 1) formed on the first substrate SUB1.

The memory devices 200, 300 of the PoC structure illustrated in FIGS. 2 and 3 and the memory devices 400, 500 of the CoP structure illustrated in FIGS. 4 and 5 may have substantially similar wiring connection structures, except that the stacking order in the third direction D3 is opposite to each other. For convenience of explanation, below, a memory device according to one embodiment of the present disclosure is described as having the PoC structure illustrated in FIGS. 2 and 3.

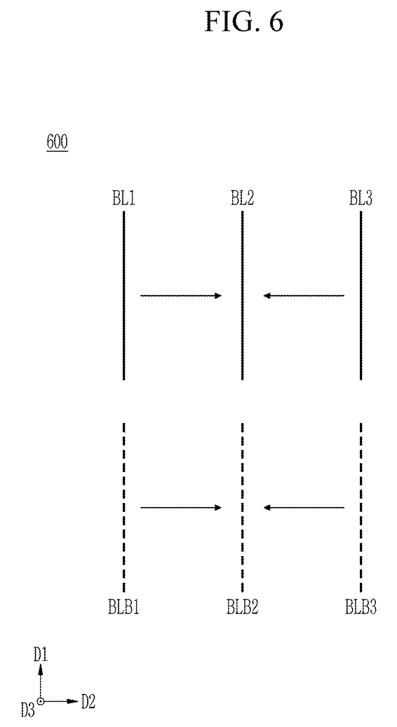

FIG. 6 is a drawing illustrating a memory device according to one embodiment of the present disclosure.

Referring to FIG. 6, the memory device 600 may include a plurality of bit lines BL1 to BL3 and a plurality of complementary bit lines BLB1 to BLB3 corresponding thereto. A plurality of bit lines BL1 to BL3 and a plurality of complementary bit lines BLB1 to BLB3 may extend along the first direction D1.

The plurality of bit lines BL1 to BL3 and the plurality of complementary bit lines BLB1 to BLB3 may be affected by coupling from adjacent bit lines and adjacent complementary bit lines. For convenience of explanation, the second bit line BL2 and the second complementary bit line BLB2 are explained below as examples.

On one side of the second bit line BL2, the first bit line BL1 is arranged adjacently and spaced apart from each other along the second direction D2, and on the other side, the third bit line BL3 is arranged adjacently and spaced apart from each other along the second direction D2. On one side of the second complementary bit line BLB2, a first complementary bit line BLB1 is arranged adjacently and spaced apart from each other along the second direction D2, and on the other side, a third complementary bit line BLB3 is arranged adjacently and spaced apart from each other along the second direction D2.

When detecting and amplifying a voltage level difference between a second bit line BL2 and a second complementary bit line BLB2, for example, the second bit line BL2 may have a high-level voltage and the second complementary bit line BLB2 may have a low-level voltage. At this time, for convenience of explanation, it is assumed that the first bit line BL1 and the third bit line BL3 have low-level voltages, and the first complementary bit line BLB1 and the third complementary bit line BLB3 have high-level voltages.

In this case, since the second bit line BL2 has a high-level voltage, while the adjacently arranged first bit line BL1 and third bit line BL3 have low-level voltages, some of the charges existing in the second bit line BL2 may flow to the first bit line BL1 and third bit line BL3 due to the coupling phenomenon. Accordingly, the voltage level of the second bit line BL2 may be lower than before.

In addition, since the second complementary bit line BLB2 has a low-level voltage, while the adjacently arranged first complementary bit line BLB1 and third complementary bit line BLB3 have high-level voltage, some of the charges existing in the first complementary bit line BLB1 and third complementary bit line BLB3 may flow to the second complementary bit line BLB2 due to the coupling phenomenon. Accordingly, the voltage level of the second complementary bit line BLB2 may be higher than before.

That is, since the voltage level difference between the second bit line BL2 and the second complementary bit line BLB2 becomes smaller than before due to the coupling phenomenon, a problem may occur in detecting and amplifying the voltage level difference between the second bit line BL2 and the second complementary bit line BLB2 by the bit line sense amplifier.

To solve this, a memory device according to an embodiment of the present disclosure described below may include a bit line and complementary bit line connection structure that allows coupling occurring between bit lines and between complementary bit lines to be canceled out by themselves, and may connect a memory region and a peripheral circuit region without signal disconnection through additional bonding pads and metal wiring.

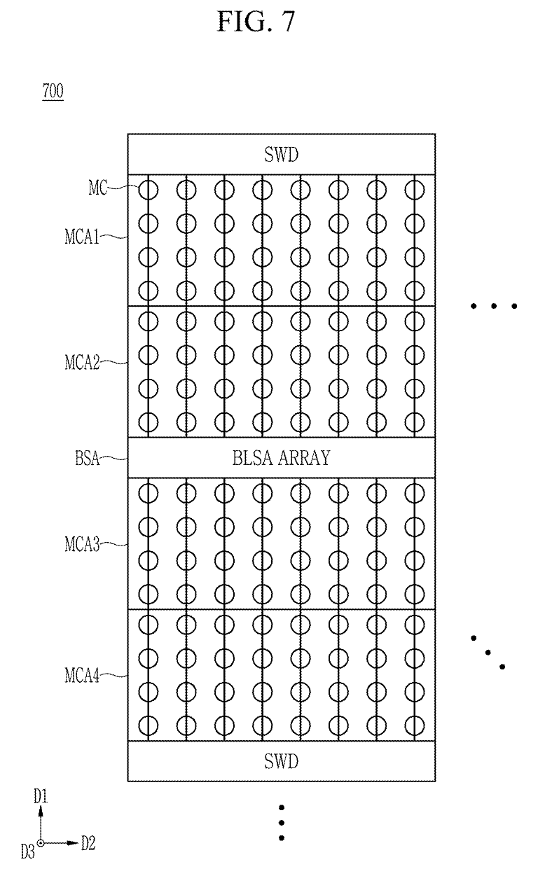

FIG. 7 is a drawing illustrating a memory device according to one embodiment of the present disclosure.

Referring to FIG. 7, the memory device 700 may include a plurality of memory cell arrays MCA1 to MCA4. The plurality of memory cell arrays MCA1 to MCA4 may include a first memory cell array MCA1, a second memory cell array MCA2, a third memory cell array MCA3, and a fourth memory cell array MCA4. The first memory cell array MCA1, the second memory cell array MCA2, the third memory cell array MCA3, and the fourth memory cell array MCA4 may be arranged spaced apart from each other along the first direction D1. The first memory cell array MCA1, the second memory cell array MCA2, the third memory cell array MCA3, and the fourth memory cell array MCA4 may be positioned on the same first substrate SUB1, for example, as illustrated in FIGS. 2 and 3.

The first memory cell array MCA1, the second memory cell array MCA2, the third memory cell array MCA3, and the fourth memory cell array MCA4 may include a plurality of bit lines, and a plurality of word lines, and a plurality of memory cells MC connected to the plurality of bit lines and the plurality of word lines.

In the sub word line driver region SWD, sub word line drivers may be placed. A sub word line driver may activate a specific word line among the plurality of word lines.

The memory device 700 may include a bit line sense amplifier array BSA. A bit line sense amplifier array BSA may include a plurality of bit line sense amplifiers. The plurality of bit line sense amplifiers may be positioned on the same second substrate SUB2, for example, as illustrated in FIGS. 2 and 3.

Meanwhile, for convenience of explanation, in FIG. 7, the bit line sense amplifier array BSA is illustrated as being positioned between the spaces along the first direction D1 of the plurality of memory cell arrays MCA1 to MCA4, but the embodiment is not limited thereto.

For example, the bit line sense amplifiers included in the bit line sense amplifier array BSA may be arranged on one of the plurality of memory cell arrays MCA1 to MCA4 along the third direction D3 such that at least a subset of the bit line sense amplifiers overlap on one of the plurality of memory cell arrays MCA1 to MCA4. Specific details will be described later.

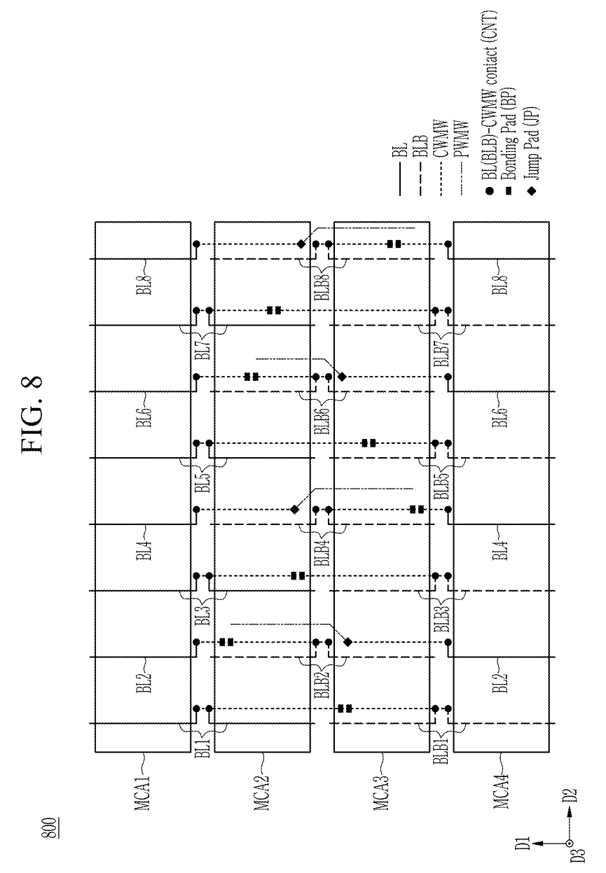

FIG. 8 is a drawing illustrating a memory device according to one embodiment of the present disclosure.

Referring to FIG. 8, the memory device 800 may include a first memory cell array MCA1, a second memory cell array MCA2, a third memory cell array MCA3, and a fourth memory cell array MCA4. The first memory cell array MCA1, the second memory cell array MCA2, the third memory cell array MCA3, and the fourth memory cell array MCA4 may be arranged spaced apart along the first direction D1.

Each of the first memory cell array MCA1, the second memory cell array MCA2, the third memory cell array MCA3, and the fourth memory cell array MCA4 may include a plurality of bit lines and a plurality of complementary bit lines corresponding thereto. The plurality of bit lines and the plurality of complementary bit lines included in each of the first memory cell array MCA1, the second memory cell array MCA2, the third memory cell array MCA3, and the fourth memory cell array MCA4 may have a structure that minimizes coupling between other adjacent bit lines and the complementary bit lines in the second direction D2.

Specifically, the first memory cell array MCA1 may include a first bit line BL1, a second bit line BL2, a third bit line BL3, a fourth bit line BL4, a fifth bit line BL5, a sixth bit line BL6, a seventh bit line BL7, and an eighth bit line BL8 extending in the first direction D1. The first bit line BL1, the second bit line BL2, the third bit line BL3, the fourth bit line BL4, the fifth bit line BL5, the sixth bit line BL6, the seventh bit line BL7, and the eighth bit line BL8 may be sequentially arranged and spaced apart along the second direction D2.

The second memory cell array MCA2 may include a first bit line BL1, a second complementary bit line BLB2, a third bit line BL3, a fourth complementary bit line BLB4, a fifth bit line BL5, a sixth complementary bit line BLB6, a seventh bit line BL7, and an eighth complementary bit line BLB8 extending in the first direction D1. The first bit line BL1, the second complementary bit line BLB2, the third bit line BL3, the fourth complementary bit line BLB4, the fifth bit line BL5, the sixth complementary bit line BLB6, the seventh bit line BL7, and the eighth complementary bit line BLB8 may be sequentially arranged and spaced apart along the second direction D2.

The third memory cell array MCA3 may include a first complementary bit line BLB1, a second complementary bit line BLB2, a third complementary bit line BLB3, a fourth complementary bit line BLB4, a fifth complementary bit line BLB5, a sixth complementary bit line BLB6, a seventh complementary bit line BLB7, and an eighth complementary bit line BLB8 extending in the first direction D1. The first complementary bit line BLB1, the second complementary bit line BLB2, the third complementary bit line BLB3, the fourth complementary bit line BLB4, the fifth complementary bit line BLB5, the sixth complementary bit line BLB6, the seventh complementary bit line BLB7, and the eighth complementary bit line BLB8 may be sequentially arranged and spaced apart along the second direction D2.

The fourth memory cell array MCA4 may include a first complementary bit line BLB1, a second bit line BL2, a third complementary bit line BLB3, a fourth bit line BL4, a fifth complementary bit line BLB5, a sixth bit line BL6, a seventh complementary bit line BLB7, and an eighth bit line BL8 extending in the first direction D1. The first complementary bit line BLB1, the second bit line BL2, the third complementary bit line BLB3, the fourth bit line BL4, the fifth complementary bit line BLB5, the sixth bit line BL6, the seventh complementary bit line BLB7, and the eighth bit line BL8 may be sequentially arranged and spaced apart along the second direction D2.

Unlike the example of the memory device 600 illustrated in FIG. 6, signal lines, arranged adjacently along the second direction D2 for any one of the plurality of bit lines of the memory device 800 according to one embodiment of the present disclosure illustrated in FIG. 8, may have half corresponding to the bit line and have remaining half corresponding to the complementary bit line, thereby suppressing the occurrence of coupling.

Specifically, as described with reference to FIG. 8, taking the second bit line BL2 as an example, a signal line arranged adjacent to the second bit line BL2 included in the first memory cell array MCA1 along the second direction D2 may correspond to the first bit line BL1 and the third bit line BL3 included in the first memory cell array MCA1.

On the other hand, a signal line arranged adjacent to the second bit line BL2 included in the fourth memory cell array MCA4 along the second direction D2 may correspond to the first complementary bit line BLB1 and the third complementary bit line BLB3 included in the fourth memory cell array MCA4.

Accordingly, the coupling occurring between the second bit line BL2 included in the first memory cell array MCA1, and the first bit line BL1 and the third bit line BL3 included in the first memory cell array MCA1 may be offset from the coupling occurring between the second bit line BL2 included in the fourth memory cell array MCA4, and the first complementary bit line BLB1 and the third complementary bit line BLB3 included in the fourth memory cell array MCA4.

In addition, signal lines, arranged adjacently along the second direction D2 for any one of the plurality of complementary bit lines of the memory device 800 according to one embodiment of the present disclosure illustrated in FIG. 8, may have half corresponding to the bit line and have remaining half corresponding to the complementary bit line, thereby suppressing the occurrence of coupling.

Specifically, as described with reference to FIG. 8, taking the second complementary bit line BLB2 as an example, a signal line arranged adjacent to the second complementary bit line BLB2 included in the second memory cell array MCA2 along the second direction D2 may correspond to the first bit line BL1 and the third bit line BL3 included in the second memory cell array MCA2.

On the other hand, a signal line arranged adjacent to the second complementary bit line BLB2 included in the third memory cell array MCA3 along the second direction D2 may correspond to the first complementary bit line BLB1 and the third complementary bit line BLB3 included in the third memory cell array MCA3.

Accordingly, the coupling occurring between the second complementary bit line BLB2 included in the second memory cell array MCA2, and the first bit line BL1 and the third bit line BL3 included in the second memory cell array MCA2 may be offset from the coupling occurring between the second complementary bit line BLB2 included in the third memory cell array MCA3, and the first complementary bit line BLB1 and the third complementary bit line BLB3 included in the third memory cell array MCA3.

The plurality of bit lines BL1 to BL8 and the plurality of complementary bit lines BLB1 to BLB8 may be connected to a cell wafer metal wiring CWMW through a bit line-cell wafer metal wiring contact or a complementary bit line-cell wafer metal wiring contact (hereinafter referred to as a contact CNT). The cell wafer metal wiring CWMW may be arranged above the plurality of bit lines BL1 to BL8 and the plurality of complementary bit lines BLB1 to BLB8 along the third direction D3. The cell wafer metal wiring CWMW may extend along the first direction D1.

Some of the cell wafer metal wiring CWMW may be connected to bonding pads BP, and others may be connected to jump pads JP. For convenience of explanation, the following description will exemplify a pad and metal wiring structure existing between a first bit line BL1 and a corresponding first complementary bit line BLB1, and a pad and metal wiring structure existing between a second bit line BL2 and a corresponding second complementary bit line BLB2.

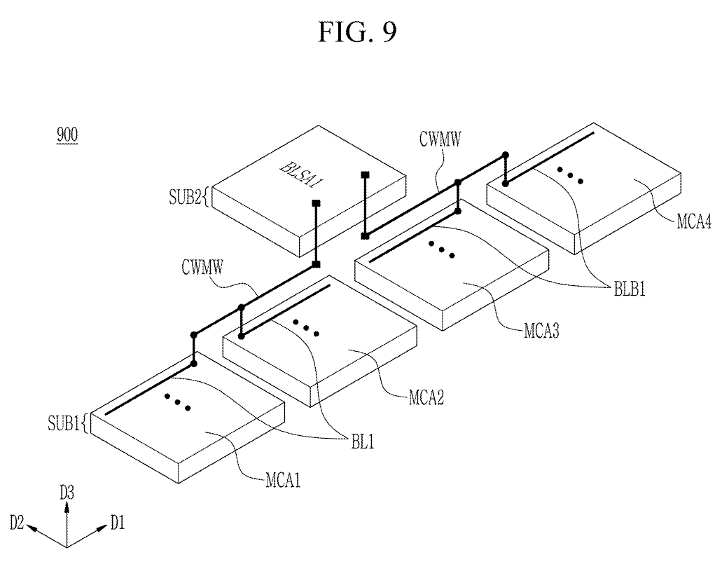

FIG. 9 is a perspective view schematically illustrating a memory device according to one embodiment of the present disclosure. Specifically, FIG. 9 is a perspective view illustrating pads and metal wiring existing between a first bit line BL1 and a first complementary bit line BLB1 among a plurality of bit lines BL1 to BL8 and a plurality of complementary bit lines BLB1 to BLB8 illustrated in FIG. 8.

Referring to FIG. 9, a memory device 900 may include a first memory cell array MCA1, a second memory cell array MCA2, a third memory cell array MCA3, and a fourth memory cell array MCA4. The first memory cell array MCA1 and the second memory cell array MCA2 may each include a first bit line BL1 extending in a first direction D1, and the third memory cell array MCA3 and the fourth memory cell array MCA4 may each include a first complementary bit line BLB1 extending in the first direction D1. The first to fourth memory cell arrays MCA1 to MCA4 may be formed on the same first substrate SUB1.

The first bit line BL1 included in the first memory cell array MCA1 and the second memory cell array MCA2 may be connected to the cell wafer metal wiring CWMW through corresponding contact CNT of FIG. 8. The cell wafer metal wiring CWMW may be positioned above the first bit line BL1 along the third direction D3. The cell wafer metal wiring CWMW connected to the first bit line BL1 via the contact CNT may extend along a first direction D1.

The first complementary bit lines BLB1 included in the third memory cell array MCA3 and the fourth memory cell array MCA4 may be connected to the cell wafer metal wiring CWMW through corresponding contacts CNT. The cell wafer metal wiring CWMW may be positioned above the first complementary bit line BLB1 along the third direction D3. The cell wafer metal wiring CWMW connected to the first complementary bit line BLB1 via the contact CNT may extend along the first direction D1.

The cell wafer metal wiring CWMW connected to the first bit line BL1 through the contact CNT may be connected to the first bit line sense amplifier BLSA1 through the bonding pad BP in FIG. 8. The cell wafer metal wiring CWMW connected to the first complementary bit line BLB1 through the contact CNT may be connected to the first bit line sense amplifier BLSA1 through the bonding pad BP. The first bit line sense amplifier BLSA1 may be formed on a second substrate SUB2, which is different from the first substrate SUB1. The second substrate SUB2 may be formed by being stacked on the first substrate SUB1 along the third direction D3.

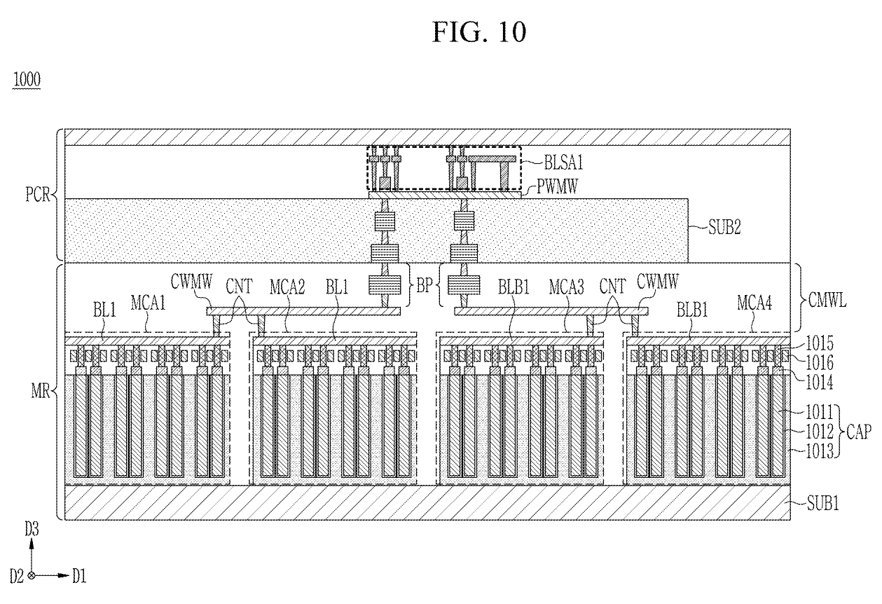

FIG. 10 is a cross-sectional view along one direction of a memory device according to one embodiment of the present disclosure. Specifically, FIG. 10 is a cross-sectional view illustrating a pad and metal wiring existing between a first bit line BL1 and a first complementary bit line BLB1 among a plurality of bit lines BL1 to BL8 and a plurality of complementary bit lines BLB1 to BLB8 illustrated in FIG. 8.

Referring to FIG. 10, a memory device 1000 may include a memory region MR and a peripheral circuit region PCR. The memory region MR may include a first substrate SUB1, a plurality of memory cell arrays MCA1 to MCA4 formed on the first substrate SUB1, and a cell metal wiring layer CMWL for connecting the plurality of memory cell arrays MCA1 to MCA4 to the peripheral circuit region PCR. The peripheral circuit region PCR may include a second substrate SUB2, a peripheral wafer metal wiring PWMW formed on the second substrate SUB2, and a first bit line sense amplifier BLSA1. The second substrate SUB2 may be formed by being stacked on the first substrate SUB1 along the third direction D3.

Each of the plurality of memory cell arrays MCA1 to MCA4 may include a plurality of cell structures that are substantially identical to each other. Specifically, each of the plurality of memory cell arrays MCA1 to MCA4 may include a capacitor structure CAP, a capacitor contact 1014, a memory channel layer 1015, and a gate electrode 1016.

The capacitor structure CAP may include a lower electrode 1011, a capacitor dielectric layer 1012, and an upper electrode 1013. The lower electrode 1011 may be electrically connected to the capacitor contact 1014. The lower electrode 1011 may be formed in a pillar type extending in the third direction D3. However, the scope of the present disclosure is not limited thereto.

The memory channel layer 1015 may be placed on the capacitor contact 1014. That is, the memory channel layer 1015 may be stacked in the third direction D3 on the capacitor contact 1014.

The gate electrode 1016 may extend in the first direction D1 from both sides of the memory channel layer 1015. An interlayer insulating film may be placed between the gate electrode 1016 and the memory channel layer 1015. The interlayer insulating film may be formed as a single continuous layer of material or as a plurality of insulating patterns.

The first memory cell array MCA1 and the second memory cell array MCA2 may include a first bit line BL1. The third memory cell array MCA3 and the fourth memory cell array MCA4 may include a first complementary bit line BLB1. The first bit line BL1 and the first complementary bit line BLB1 may extend along the first direction D1.

A cell metal wiring layer CMWL may be arranged on the plurality of memory cell arrays MCA1 to MCA4. The cell metal wiring layer CMWL may include a cell wafer metal wiring CWMW positioned above the bit line and the complementary bit line along a third direction D3, a contact CNT connecting the cell wafer metal wiring CWMW and the corresponding bit line and the complementary bit line, and a bonding pad BP connecting the cell wafer metal wiring CWMW and a peripheral circuit region PCR.

Specifically, a first bit line BL1 included in the first memory cell array MCA1 and the first bit line BL1 included in the second memory cell array MCA2 may be connected to the same cell wafer metal wiring CWMW through the contact CNT. The first complementary bit line BLB1 included in the third memory cell array MCA3 and the first complementary bit line BLB1 included in the fourth memory cell array MCA4 may be connected to the same cell wafer metal wiring CWMW through a contact CNT.

The cell wafer metal wiring CWMW connected to the first bit line BL1 may be connected to the second substrate SUB2 through the corresponding bonding pad BP positioned thereon along the third direction D3, and may be connected to the first bit line sense amplifier BLSA1 through a connection structure of the second substrate SUB2. The cell wafer metal wiring CWMW connected to a first complementary bit line BLB1 may be connected to the second substrate SUB2 through corresponding bonding pad BP positioned thereon along the third direction D3, and may be connected to the first bit line sense amplifier BLSA1 through the connection structure of the second substrate SUB2.

The peripheral circuit region PCR may include a second substrate SUB2 and a first bit line sense amplifier BLSA1 formed thereon. Although not shown, the peripheral circuit region PCR may include an interlayer insulating film, a plurality of circuit elements formed on a second substrate SUB2, and a plurality of metal layers connected to the plurality of circuit elements. Each of the plurality of metal layers may be implemented with a material having different resistance.

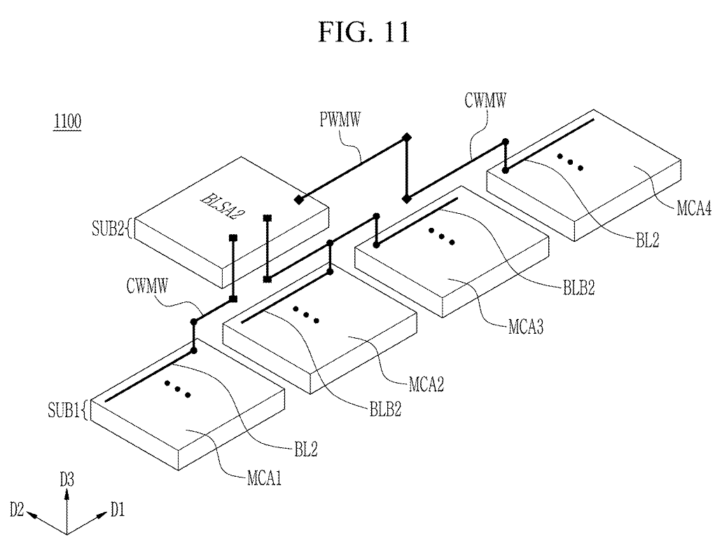

FIG. 11 is a perspective view schematically illustrating a memory device according to one embodiment of the present disclosure. Specifically, FIG. 11 is a perspective view illustrating pads and metal wiring existing between a second bit line BL2 and a second complementary bit line BLB2 among a plurality of bit lines BL1 to BL8 and a plurality of complementary bit lines BLB1 to BLB8 illustrated in FIG. 8.

Referring to FIG. 11, a memory device 1100 may include a first memory cell array MCA1, a second memory cell array MCA2, a third memory cell array MCA3, and a fourth memory cell array MCA4. The first memory cell array MCA1 and the fourth memory cell array MCA4 may each include a second bit line BL2 extending in a first direction D1, and the second memory cell array MCA2 and the third memory cell array MCA3 may each include a second complementary bit line BLB2 extending in the first direction D1. The first to fourth memory cell arrays MCA1 to MCA4 may be formed on the same first substrate SUB1.

The second bit lines BL2 included in the first memory cell array MCA1 and the fourth memory cell array MCA4 may be connected to the cell wafer metal wiring CWMW through corresponding contacts CNT of FIG. 8. The cell wafer metal wiring CWMW may be positioned above the second bit line BL2 along the third direction D3. The cell wafer metal wiring CWMW connected to the second bit line BL2 via the contact CNT may extend along the first direction D1.

The second complementary bit lines BLB2 included in the second memory cell array MCA2 and the third memory cell array MCA3 may be connected to the cell wafer metal wiring CWMW through corresponding contacts CNT. The cell wafer metal wiring CWMW may be positioned above the second complementary bit line BLB2 along the third direction D3. The cell wafer metal wiring CWMW connected to the second complementary bit line BLB2 via the contact CNT may extend along the first direction D1.

The cell wafer metal wiring CWMW connected to the second bit line BL2 included in a first memory cell array MCA1 through the contact CNT may be connected to the second bit line sense amplifier BLSA2 through the bonding pad BP in FIG. 8. The cell wafer metal wiring CWMW connected to the second complementary bit line BLB2 through the contact CNT may be connected to the second bit line sense amplifier BLSA2 through the bonding pad BP. The second bit line sense amplifier BLSA2 may be formed on a second substrate SUB2, which is different from the first substrate SUB1. The second substrate SUB2 may be formed by being stacked on the first substrate SUB1 along the third direction D3.

Meanwhile, unlike the connection structure of the first bit line BL1 described with reference to FIGS. 9 and 10, the second bit line BL2 is not arranged in an adjacent memory cell array. Specifically, the first bit line BL1 may be arranged in the first memory cell array MCA1 and the second memory cell array MCA2 which are adjacent to each other, while the second bit line BL2 may be arranged in the first memory cell array MCA1 and the fourth memory cell array MCA4 which are not adjacent to each other. Therefore, a separate pad may be required to connect the second bit line BL2 arranged in the fourth memory cell array MCA4 to the second bit line sense amplifier BLSA2.

Specifically, as illustrated in FIG. 11, the cell wafer metal wiring CWMW connected to the second bit line BL2 included in the fourth memory cell array MCA4 through the contact CNT may be connected to the second bit line sense amplifier BLSA2 through a jump pad JP of FIG. 8. More specifically, the cell wafer metal wiring CWMW connected to the second bit line BL2 included in the fourth memory cell array MCA4 may be connected to a peripheral wafer metal wiring PWMW formed on the second substrate SUB2 through the jump pad JP, and may be connected to the second bit line sense amplifier BLSA2 through the peripheral wafer metal wiring PWMW.

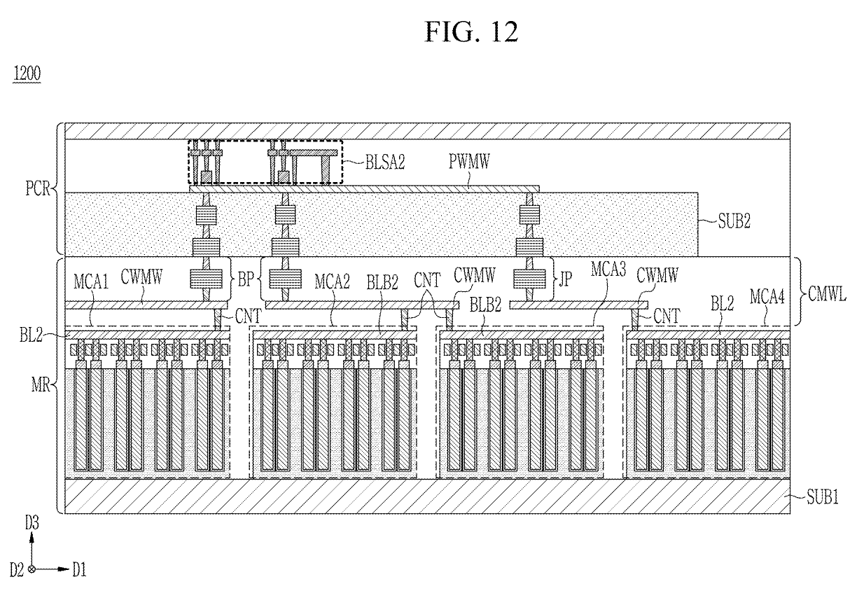

FIG. 12 is a cross-sectional view along one direction of a memory device according to one embodiment of the present disclosure. Specifically, FIG. 12 is a cross-sectional view illustrating pads and metal wiring existing between a second bit line BL2 and a second complementary bit line BLB2 among a plurality of bit lines BL1 to BL8 and a plurality of complementary bit lines BLB1 to BLB8 illustrated in FIG. 8. Below, the differences from the memory device 1000 illustrated in FIG. 10 will be mainly explained.

Referring to FIG. 12, the memory device 1200 may include a plurality of memory cell arrays MCA1 to MCA4. The first memory cell array MCA1 and the fourth memory cell array MCA4 may include a second bit line BL2. The second memory cell array MCA2 and the third memory cell array MCA3 may include a second complementary bit line BLB2. The second bit line BL2 and the second complementary bit line BLB2 may extend along the first direction D1.

A cell metal wiring layer CMWL may be arranged on the plurality of memory cell arrays MCA1 to MCA4. The cell metal wiring layer CMWL may include a cell wafer metal wiring CWMW positioned above the bit line and the complementary bit line along a third direction D3, a contact CNT connecting the cell wafer metal wiring CWMW and the corresponding bit line and the complementary bit line, a bonding pad BP and a jump pad JP for connecting the cell wafer metal wiring CWMW and a peripheral circuit region PCR.

Specifically, the second bit line BL2 included in the first memory cell array MCA1 may be connected to the cell wafer metal wiring CWMW through the contact CNT. The second complementary bit line BLB2 included in the second memory cell array MCA2 and the second complementary bit line BLB2 included in the third memory cell array MCA3 may be connected to the same cell wafer metal wiring CWMW through the contact CNT. The second bit line BL2 included in the fourth memory cell array MCA4 may be connected to the cell wafer metal wiring CWMW through the contact CNT.

The cell wafer metal wiring CWMW connected to the second bit line BL2 included in the first memory cell array MCA1 may be connected to the second substrate SUB2 through corresponding bonding pad BP positioned thereon along a third direction D3, and may be connected to the second bit line sense amplifier BLSA2 through a connection structure of the second substrate SUB2. The cell wafer metal wiring CWMW connected to the second complementary bit line BLB2 may be connected to the second substrate SUB2 through corresponding bonding pad BP positioned thereon along the third direction D3, and may be connected to the second bit line sense amplifier BLSA2 through a connection structure of the second substrate SUB2. The cell wafer metal wiring CWMW connected to the second bit line BL2 included in the fourth memory cell array MCA4 may be connected to the second substrate SUB2 through corresponding jump pad JP positioned thereon along the third direction D3, and may be connected to a peripheral wafer metal wiring PWMW through a connection structure of the second substrate SUB2, thereby being connected to the second bit line sense amplifier BLSA2.

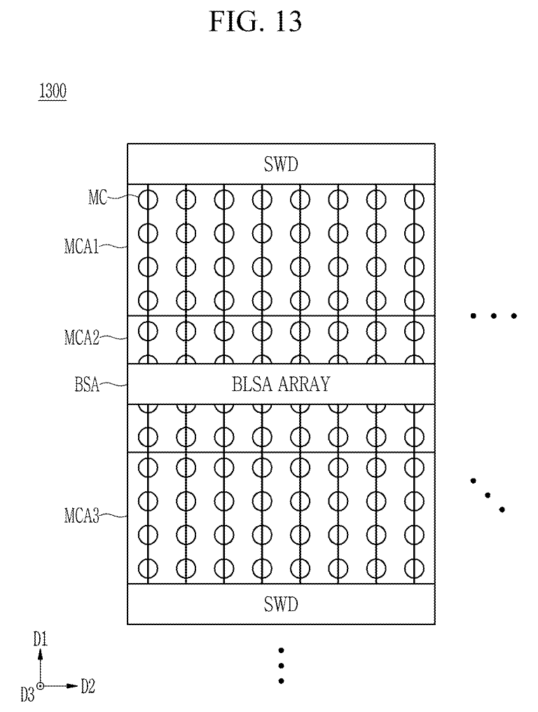

FIG. 13 is a drawing illustrating a memory device according to one embodiment of the present disclosure.

Referring to FIG. 13, a memory device 1300 may include a plurality of memory cell arrays MCA1 to MCA3. The plurality of memory cell arrays MCA1 to MCA3 may include a first memory cell array MCA1, a second memory cell array MCA2, and a third memory cell array MCA3. The first memory cell array MCA1, the second memory cell array MCA2, and the third memory cell array MCA3 may be arranged spaced apart along the first direction D1. The first memory cell array MCA1, the second memory cell array MCA2, and the third memory cell array MCA3 may be positioned on the same first substrate SUB1, for example, as illustrated in FIGS. 2 and 3.

The first memory cell array MCA1, the second memory cell array MCA2, and the third memory cell array MCA3 may include a plurality of bit lines and a plurality of word lines, and a plurality of memory cells MC connected to the plurality of bit lines and the plurality of word lines.

In the sub word line driver region SWD, sub word line drivers may be placed. A sub word line driver may activate a specific word line among the plurality of word lines.

The memory device 1300 may include a bit line sense amplifier array BSA. A bit line sense amplifier array BSA may include a plurality of bit line sense amplifiers. The plurality of bit line sense amplifiers may be positioned on the same second substrate SUB2, for example, as illustrated in FIGS. 2 and 3.

Meanwhile, for convenience of explanation, in FIG. 13, the bit line sense amplifier array BSA is illustrated as being positioned between the spaces along the first direction D1 of the plurality of memory cell arrays MCA1 to MCA3, but the embodiment is not limited thereto.

For example, the bit line sense amplifiers included in the bit line sense amplifier array BSA may be arranged on one of the plurality of memory cell arrays MCA1 to MCA3 along the third direction D3 such that at least a subset of the bit line sense amplifiers overlap on one of the plurality of memory cell arrays MCA1 to MCA3. Specific details will be described later.

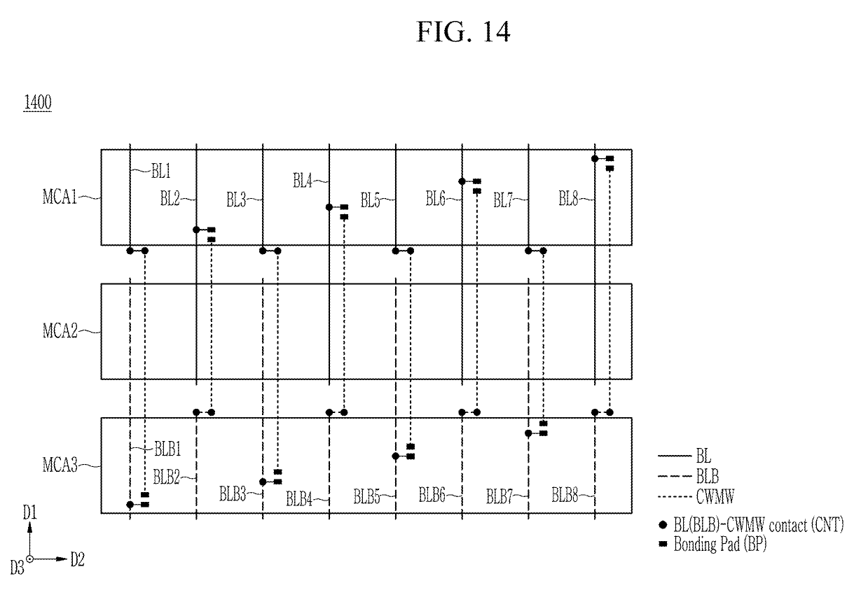

FIG. 14 is a drawing illustrating a memory device according to one embodiment of the present disclosure.

Referring to FIG. 14, a memory device 1400 may include a first memory cell array MCA1, a second memory cell array MCA2, and a third memory cell array MCA3. The first memory cell array MCA1, the second memory cell array MCA2, and the third memory cell array MCA3 may be arranged spaced apart along the first direction D1.

Each of the first memory cell array MCA1, the second memory cell array MCA2, and the third memory cell array MCA3 may include a plurality of bit lines and a plurality of complementary bit lines corresponding thereto. The plurality of bit lines and the plurality of complementary bit lines included in each of the first memory cell array MCA1, the second memory cell array MCA2, and the third memory cell array MCA3 may have a structure that minimizes coupling between other adjacent bit lines and the complementary bit lines in the second direction D2.

Specifically, the first memory cell array MCA1 may include a first bit line BL1, a second bit line BL2, a third bit line BL3, a fourth bit line BL4, a fifth bit line BL5, a sixth bit line BL6, a seventh bit line BL7, and an eighth bit line BL8 extending in the first direction D1. The first bit line BL1, the second bit line BL2, the third bit line BL3, the fourth bit line BL4, the fifth bit line BL5, the sixth bit line BL6, the seventh bit line BL7, and the eighth bit line BL8 may be sequentially arranged and spaced apart along the second direction D2.

The second memory cell array MCA2 may include a first complementary bit line BLB1, a second bit line BL2, a third complementary bit line BLB3, a fourth bit line BL4, a fifth complementary bit line BLB5, a sixth bit line BL6, a seventh complementary bit line BLB7, and an eighth bit line BL8 extending in the first direction D1. The first complementary bit line BLB1, the second bit line BL2, the third complementary bit line BLB3, the fourth bit line BL4, the fifth complementary bit line BLB5, the sixth bit line BL6, the seventh complementary bit line BLB7, and the eighth bit line BL8 may be sequentially arranged and spaced apart along the second direction D2.

The third memory cell array MCA3 may include a first complementary bit line BLB1, a second complementary bit line BLB2, a third complementary bit line BLB3, a fourth complementary bit line BLB4, a fifth complementary bit line BLB5, a sixth complementary bit line BLB6, a seventh complementary bit line BLB7, and an eighth complementary bit line BLB8 extending in the first direction D1. The first complementary bit line BLB1, the second complementary bit line BLB2, the third complementary bit line BLB3, the fourth complementary bit line BLB4, the fifth complementary bit line BLB5, the sixth complementary bit line BLB6, the seventh complementary bit line BLB7, and the eighth complementary bit line BLB8 may be sequentially arranged and spaced apart along the second direction D2.

Unlike the example of the memory device 600 illustrated in FIG. 6, signal lines, arranged adjacently along the second direction D2 for any one of the plurality of bit lines of the memory device 1400 according to one embodiment of the present disclosure illustrated in FIG. 14, may have half corresponding to the bit line and have remaining half corresponding to the complementary bit line, thereby suppressing the occurrence of coupling.

Specifically, as described with reference to FIG. 14, taking the second bit line BL2 as an example, a signal line arranged adjacent to the second bit line BL2 included in the first memory cell array MCA1 along the second direction D2 may correspond to the first bit line BL1 and the third bit line BL3 included in the first memory cell array MCA1.

On the other hand, a signal line arranged adjacent to the second bit line BL2 included in the second memory cell array MCA2 along the second direction D2 may correspond to the first complementary bit line BLB1 and the third complementary bit line BLB3 included in the second memory cell array MCA2.

Accordingly, the coupling occurring between the second bit line BL2 included in the first memory cell array MCA1, and the first bit line BL1 and the third bit line BL3 included in the first memory cell array MCA1 may be offset from the coupling occurring between the second bit line BL2 included in the second memory cell array MCA2, and the first complementary bit line BLB1 and the third complementary bit line BLB3 included in the second memory cell array MCA2.

In addition, signal lines, arranged adjacently along the second direction D2 for any one of the plurality of complementary bit lines of the memory device 1400 according to one embodiment of the present disclosure illustrated in FIG. 14, may have half corresponding to the bit line and have remaining half corresponding to the complementary bit line, thereby suppressing the occurrence of coupling.

Specifically, as described with reference to FIG. 14, taking the second complementary bit line BLB2 as an example, a signal line arranged adjacent to the second complementary bit line BLB2 included in the third memory cell array MCA3 along the second direction D2 may correspond to the first complementary bit line BLB1 and the third complementary bit line BLB3 included in the third memory cell array MCA3.

Meanwhile, the second complementary bit line BLB2 included in the third memory cell array MCA3 may be connected to the cell wafer metal wiring CWMW positioned thereon through a contact CNT, and the cell wafer metal wiring CWMW may be considered as an extension of the second complementary bit line BLB2. In addition, each of the first bit line BL1 and the third bit line BL3 included in the first memory cell array MCA1 may be connected to a cell wafer metal wiring CWMW positioned thereon through a contact CNT, and the cell wafer metal wiring CWMW may be considered as an extension of the first bit line BL1 and the third bit line BL3, respectively.

Accordingly, a signal line arranged adjacent to a cell wafer metal wiring CWMW connected to a second complementary bit line BLB2 included in a third memory cell array MCA3 along the second direction D2 on the second memory cell array MCA2 may correspond to a cell wafer metal wiring CWMW connected to a first bit line BL1 included in the first memory cell array MCA1 and a cell wafer metal wiring CWMW connected to a third bit line BL3 included in the first memory cell array MCA1.

Accordingly, the coupling occurring between the second complementary bit line BLB2 included in the third memory cell array MCA3, and the first complementary bit line BLB1 and the third complementary bit line BLB3 included in the third memory cell array MCA3 may be offset from the coupling occurring between the cell wafer metal wiring CWMW positioned on the second memory cell array MCA2 to which the second complementary bit line BLB2 included in the third memory cell array MCA3 is connected and the cell wafer metal wiring CWMW positioned on the second memory cell array MCA2 to which the first bit line BL1 and the third bit line BL3 included in the first memory cell array MCA1 are connected.

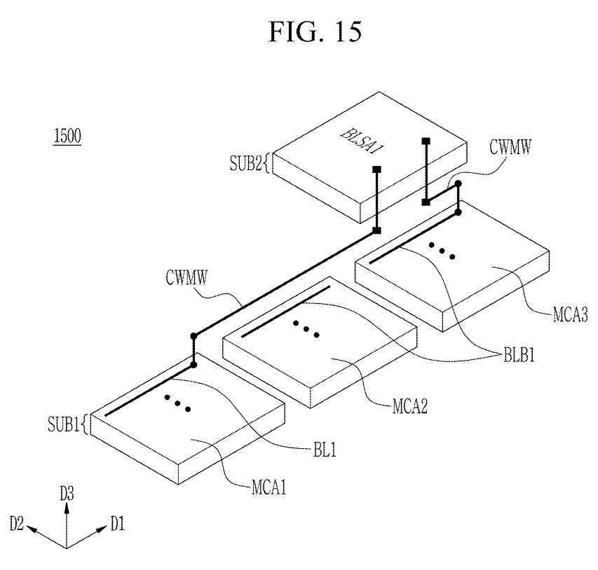

FIG. 15 is a perspective view schematically illustrating a memory device according to one embodiment of the present disclosure. Specifically, FIG. 15 is a perspective view illustrating pads and metal wiring existing between a first bit line BL1 and a first complementary bit line BLB1 among a plurality of bit lines BL1 to BL8 and a plurality of complementary bit lines BLB1 to BLB8 illustrated in FIG. 14.

Referring to FIG. 15, a memory device 1500 may include a first memory cell array MCA1, a second memory cell array MCA2, and a third memory cell array MCA3. The first memory cell array MCA1 may include a first bit line BL1 extending in a first direction D1, and the second memory cell array MCA2 and the third memory cell array MCA3 may each include a first complementary bit line BLB1 extending in the first direction D1. The first to third memory cell arrays MCA1 to MCA3 may be formed on the same first substrate SUB1.

A first bit line BL1 included in a first memory cell array MCA1 may be connected to a cell wafer metal wiring CWMW through corresponding contact CNT of FIG. 14. The cell wafer metal wiring CWMW may be positioned above the first bit line BL1 along the third direction D3. The cell wafer metal wiring CWMW connected to the first bit line BL1 via the contact CNT may extend along a first direction D1.

The first complementary bit line BLB1 included in the third memory cell array MCA3 may be connected to a cell wafer metal wiring CWMW through corresponding contact CNT. The cell wafer metal wiring CWMW may be positioned above the first complementary bit line BLB1 along the third direction D3. The cell wafer metal wiring CWMW connected to the first complementary bit line BLB1 via the contact CNT may extend along the first direction D1.

The cell wafer metal wiring CWMW connected to the first bit line BL1 through the contact CNT may be connected to the first bit line sense amplifier BLSA1 through the bonding pad BP in FIG. 14. The cell wafer metal wiring CWMW connected to the first complementary bit line BLB1 through the contact CNT may be connected to the first bit line sense amplifier BLSA1 through the bonding pad BP. The first bit line sense amplifier BLSA1 may be formed on a second substrate SUB2, which is different from the first substrate SUB1. The second substrate SUB2 may be formed by being stacked on the first substrate SUB1 along the third direction D3.

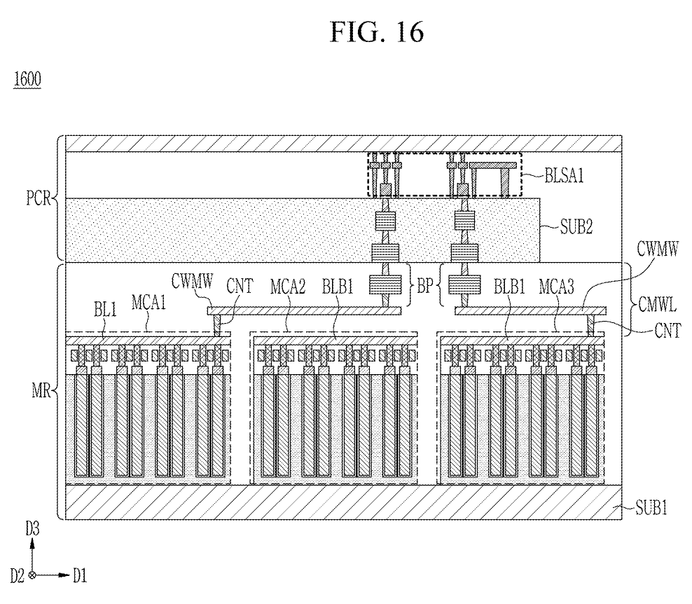

FIG. 16 is a cross-sectional view along one direction of a memory device according to one embodiment of the present disclosure. Specifically, FIG. 16 is a cross-sectional view illustrating a pad and metal wiring existing between a first bit line BL1 and a first complementary bit line BLB1 among a plurality of bit lines BL1 to BL8 and a plurality of complementary bit lines BLB1 to BLB8 illustrated in FIG. 14. Below, the differences from the memory device 1000 illustrated in FIG. 10 and the memory device 1200 illustrated in FIG. 12 will be mainly described.

Referring to FIG. 16, the memory device 1600 may include a plurality of memory cell arrays MCA1 to MCA3. The first memory cell array MCA1 may include a first bit line BL1. The second memory cell array MCA2 and the third memory cell array MCA3 may include a first complementary bit line BLB1. The first bit line BL1 and the first complementary bit line BLB1 may extend along the first direction D1.

A cell metal wiring layer CMWL may be arranged on the plurality of memory cell arrays MCA1 to MCA3. The cell metal wiring layer CMWL may include a cell wafer metal wiring CWMW positioned above the bit line and the complementary bit line along a third direction D3, a contact CNT connecting the cell wafer metal wiring CWMW and the corresponding bit line and the complementary bit line, and a bonding pad BP connecting the cell wafer metal wiring CWMW and a peripheral circuit region PCR.

Specifically, a first bit line BL1 included in a first memory cell array MCA1 may be connected to the cell wafer metal wiring CWMW through the contact CNT. The first complementary bit line BLB1 included in the third memory cell array MCA3 may be connected to the cell wafer metal wiring CWMW through the contact CNT.

The cell wafer metal wiring CWMW connected to the first bit line BL1 included in the first memory cell array MCA1 may be connected to a second substrate SUB2 through corresponding bonding pad BP positioned thereon along the third direction D3, and may be connected to the first bit line sense amplifier BLSA1 through a connection structure of the second substrate SUB2. The cell wafer metal wiring CWMW connected to the first complementary bit line BLB1 included in the third memory cell array MCA3 may be connected to the second substrate SUB2 through corresponding bonding pad BP positioned thereon along the third direction D3, and may be connected to the first bit line sense amplifier BLSA1 through a connection structure of the second substrate SUB2.

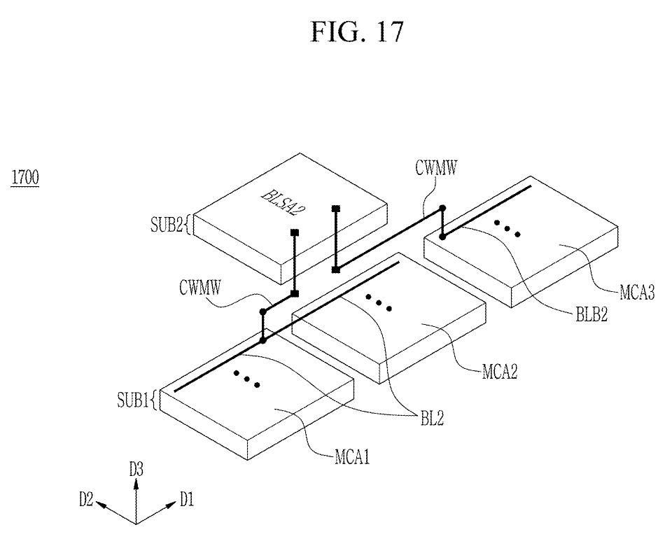

FIG. 17 is a perspective view schematically illustrating a memory device according to one embodiment of the present disclosure. Specifically, FIG. 17 is a perspective view illustrating pads and metal wiring existing between a second bit line BL2 and a second complementary bit line BLB2 among a plurality of bit lines BL1 to BL8 and a plurality of complementary bit lines BLB1 to BLB8 illustrated in FIG. 14.

Referring to FIG. 17, a memory device 1700 may include a first memory cell array MCA1, a second memory cell array MCA2, and a third memory cell array MCA3. The first memory cell array MCA1 and the second memory cell array MCA2 may each include a second bit line BL2 extending in the first direction D1, and the third memory cell array MCA3 may include a second complementary bit line BLB2 extending in the first direction D1. The first to third memory cell arrays MCA1 to MCA3 may be formed on the same first substrate SUB1.

The second bit line BL2 included in the first memory cell array MCA1 may be connected to the cell wafer metal wiring CWMW through corresponding contact CNT of FIG. 14. The cell wafer metal wiring CWMW may be positioned above the second bit line BL2 along the third direction D3. The cell wafer metal wiring CWMW connected to the second bit line BL2 via the contact CNT may extend along the first direction D1.

The second complementary bit line BLB2 included in the third memory cell array MCA3 may be connected to the cell wafer metal wiring CWMW through corresponding contact CNT. The cell wafer metal wiring CWMW may be positioned above the second complementary bit line BLB2 along the third direction D3. The cell wafer metal wiring CWMW connected to the second complementary bit line BLB2 via the contact CNT may extend along the first direction D1.

The cell wafer metal wiring CWMW connected to the second bit line BL2 through the contact CNT may be connected to the second bit line sense amplifier BLSA2 through the bonding pad BP in FIG. 14. The cell wafer metal wiring CWMW connected to the second complementary bit line BLB2 through the contact CNT may be connected to the second bit line sense amplifier BLSA2 through the bonding pad BP. The second bit line sense amplifier BLSA2 may be formed on a second substrate SUB2, which is different from the first substrate SUB1. The second substrate SUB2 may be formed by being stacked on the first substrate SUB1 along the third direction D3.

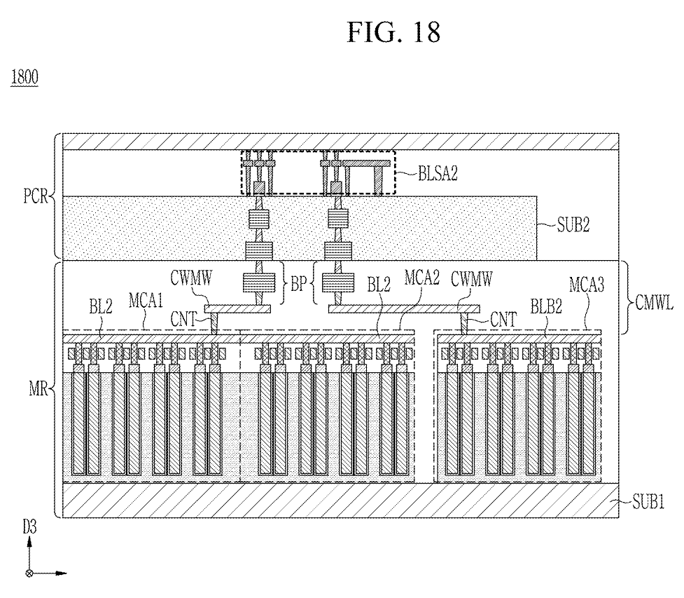

FIG. 18 is a cross-sectional view along one direction of a memory device according to one embodiment of the present disclosure. Specifically, FIG. 18 is a cross-sectional view illustrating pads and metal wiring existing between a second bit line BL2 and a second complementary bit line BLB2 among a plurality of bit lines BL1 to BL8 and a plurality of complementary bit lines BLB1 to BLB8 illustrated in FIG. 14. Below, the differences from the memory device 1000 illustrated in FIG. 10, the memory device 1200 illustrated in FIG. 12, and the memory device 1600 illustrated in FIG. 16 will be mainly described.

Referring to FIG. 18, the memory device 1800 may include a plurality of memory cell arrays MCA1 to MCA3. The first memory cell array MCA1 and the second memory cell array MCA2 may include a second bit line BL2. The third memory cell array MCA3 may include a second complementary bit line BLB2. The second bit line BL2 and the second complementary bit line BLB2 may extend along the first direction D1.

A cell metal wiring layer CMWL may be arranged on the plurality of memory cell arrays MCA1 to MCA3. The cell metal wiring layer CMWL may include a cell wafer metal wiring CWMW positioned above the bit line and the complementary bit line along a third direction D3, a contact CNT connecting the cell wafer metal wiring CWMW and the corresponding bit line and the complementary bit line, and a bonding pad BP connecting the cell wafer metal wiring CWMW and a peripheral circuit region PCR.

Specifically, the second bit line BL2 included in the first memory cell array MCA1 may be connected to the cell wafer metal wiring CWMW through the contact CNT. The second complementary bit line BLB2 included in the third memory cell array MCA3 may be connected to the cell wafer metal wiring CWMW through the contact CNT.

The cell wafer metal wiring CWMW connected to the second bit line BL2 included in the first memory cell array MCA1 may be connected to the second substrate SUB2 through corresponding bonding pad BP positioned thereon along the third direction D3, and may be connected to the second bit line sense amplifier BLSA2 through a connection structure of the second substrate SUB2. The cell wafer metal wiring CWMW connected to the second complementary bit line BLB2 included in the third memory cell array MCA3 may be connected to the second substrate SUB2 through corresponding bonding pad BP positioned thereon along the third direction D3, and may be connected to the second bit line sense amplifier BLSA2 through a connection structure of the second substrate SUB2.

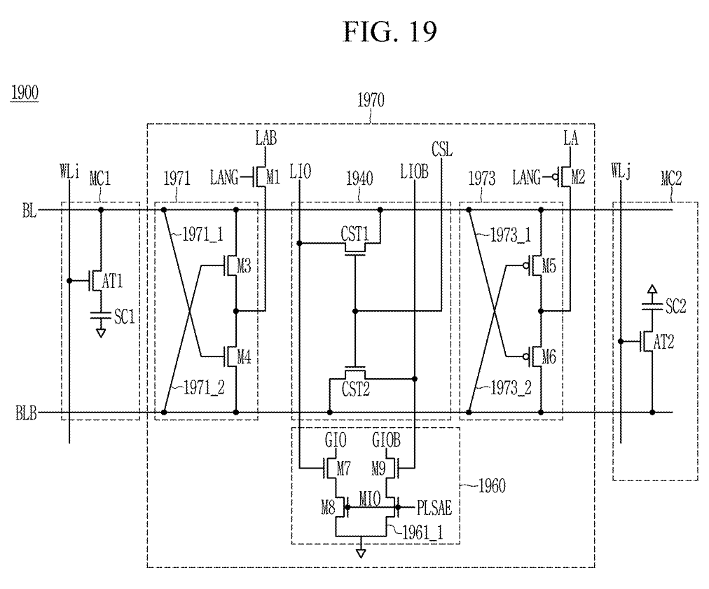

FIG. 19 is a diagram illustrating a bit line sense amplifier included in a memory device according to one embodiment of the present disclosure.

Referring to FIG. 19, a bit line sense amplifier 1900 may be connected to a bit line BL and a complementary bit line BLB. The bit line BL may be any one of the plurality of bit lines BL1 to BL8 illustrated in FIGS. 7 to 18, and the complementary bit line BLB may be any one of the plurality of complementary bit lines BLB1 to BLB8 illustrated in FIGS. 7 to 18, corresponding to the bit line BL.

A plurality of memory cells may be connected to a bit line BL, and a plurality of word lines WL may be connected to each of the plurality of memory cells. Additionally, the plurality of memory cells may be connected to complementary bit lines BLB, and the plurality of word lines WL may be connected to each of the plurality of memory cells.

In some embodiments, the bit line sense amplifier 1900 may be connected to one of the bit line BL and the complementary bit line BLB. For convenience of explanation, FIG. 19 illustrates one memory cell MC1 connected to a bit line BL, one word line WLi connected to the memory cell MC1, one memory cell MC2 connected to a complementary bit line BLB, and one word line WLj connected to the memory cell MC2.

In addition, although FIG. 19 illustrates that the memory cell MC1 includes a switching transistor AT1 and a capacitor SC1, and that the memory cell MC2 includes a switching transistor AT2 and a capacitor SC2, the structure of the memory cells MC1, MC2 is not limited thereto.

The bit line sense amplifier 1900 may include an N-type sense amplifier 1971, a P-type sense amplifier 1973, an input/output gate circuit 1940, a local sense amplifier 1960, and transistors M1, M2. In some embodiments, the plurality of transistors M1 to M10, CST1, CST2 illustrated in FIG. 19 may be metal oxide semiconductor MOS transistors. In some embodiments, the plurality of transistors M1, M3, M4, M7, M8, M9, M10, CST1, CST2 may be n-channel transistors, for example, NMOS transistors. Additionally, the transistors M2, M5, M6 may be p-channel transistors, for example, PMOS transistors. The transistors M1 to M10, CST1, CST2 may have their respective sources, drains, and gates as the first input terminal, the second input terminal, and the control terminal.

The N-type sense amplifier 1971 may include a third transistor M3 and a fourth transistor M4. The gate of the third transistor M3 may be electrically connected to the complementary bit line BLB through a conductive line 1971_2. The gate of the fourth transistor M4 may be electrically connected to the bit line BL through a conductive line 1971_1. The source of the third transistor M3 and the source of the fourth transistor M4 may be electrically connected to the bit line BL and the complementary bit line BLB, respectively. A first voltage LAB may be input to the drain of the third transistor M3 and the drain of the fourth transistor M4 in response to the N-type sense amplifier driving signal LANG. The N-type sense amplifier driving signal LANG may have an active level e.g., a high level for turning on the first transistor M1 or an inactive level e.g., a low level for turning off the first transistor M1. The first voltage LAB may be ground voltage.

The third transistor M3 and the fourth transistor M4 may be turned on or off depending on the voltage change of the bit line BL or the complementary bit line BLB. When the third transistor M3 is turned on, the first voltage LAB may be provided to the bit line BL. When the fourth transistor M4 is turned on, the first voltage LAB may be provided to the complementary bit line BLB.

The P-type sense amplifier 1973 may include a fifth transistor M5 and a sixth transistor M6. The gate of the fifth transistor M5 may be electrically connected to the complementary bit line BLB through a conductive line 1973_2. The gate of the sixth transistor M6 may be electrically connected to the bit line BL through a conductive line 1973_1. The source of the fifth transistor M5 and the source of the sixth transistor M6 may be electrically connected to the bit line BL and the complementary bit line BLB, respectively. A second voltage LA may be input to the drain of the fifth transistor M5 and the drain of the sixth transistor M6 in response to the P-type sense amplifier driving signal LAPG. The P-type sense amplifier driving signal LAPG may have an active level e.g., a low level for turning on the second transistor M2 or an inactive level e.g., a high level for turning off the second transistor M2. The second voltage LA may be a power supply voltage.

The fifth transistor M5 and the sixth transistor M6 may be turned on or off depending on the voltage change of the bit line BL or the complementary bit line BLB. When the fifth transistor M5 is turned on, the second voltage LA may be provided to the bit line BL. When the sixth transistor M6 is turned on, the second voltage LA may be provided to the complementary bit line BLB.

The input/output gate circuit 1940 may include a first column select transistor CST1 and a second column select transistor CST2. The drain of the first column select transistor CST1 may be electrically connected to the bit line BL, and the drain of the second column select transistor CST2 may be electrically connected to the complementary bit line BLB. The source of the first column select transistor CST1 may be electrically connected to a local input/output line LIO, and the source of the second column select transistor CST2 may be electrically connected to a complementary local input/output line LIOB. A column select line CSL may be connected to the gate of the first column select transistor CST1 and the gate of the second column select transistor CST2. A bit line pair BL, BLB connected to a sense amplifier 1970 may be connected to a local input/output line pair LIO, LIOB through the column select transistor CST1, CST2.

The column select transistors CST1, CST2 in the input/output gate circuit 1940 may transmit potentials output from the N-type sense amplifier 1971 and the P-type sense amplifier 1973 to the local sense amplifier 1960 in response to the column select signal of the column select line CSL.

The local sense amplifier 1960 may include a seventh transistor M7, an eighth transistor M8, a ninth transistor M9, and a tenth transistor M10. The seventh transistor M7, the eighth transistor M8, the ninth transistor M9, and the tenth transistor M10 may be electrically connected within the local sense amplifier 1960 through a conductive line 1961_1.

A local enable signal PLSAE may be input to the gate of the eighth transistor M8 and the gate of the tenth transistor M10. The gate of the eighth transistor M8 and the tenth transistor M10 are turned on through the local enable signal PLSAE, so that the local sense amplifier 1960 may be activated. When the local sense amplifier 1960 is activated, the seventh transistor M7 and the ninth transistor M9 may invert and output data of the local input/output line pair LIO, LIOB to the global input/output line pair GIO, GIOB, respectively.

The bit line sense amplifier 1900 may operate as follows. First, when the word line WLi, WLj is activated, the switching transistor AT1 of the memory cell MC1 is turned on so that charge may move between the bit line BL and the capacitor SC1 in the memory cell MC1, and the switching transistor AT2 of the memory cell MC2 is turned on so that charge may move between the complementary bit line BLB and the capacitor SC2 in the memory cell MC2. Afterwards, an N-type sense amplifier 1971 or a P-type sense amplifier 1973 amplifies the potential difference between the bit line BL and the complementary bit line BLB. Then, when the column select signal becomes an active level, the input/output gate circuit 1940 may output data of a bit line BL or a complementary bit line BLB through a local input/output line LIO or a complementary local input/output line LIOB, respectively. That is, in response to the column selection signal, the column selection transistors CST1, CST2 in the input/output gate circuit 1940 may transmit the potential output from the N-type sense amplifier 1971 or the P-type sense amplifier 1973 to the local sense amplifier 1960. The local sense amplifier 1960 is activated by the local enable signal PLSAE to invert the data of the received local input/output line pair LIO, LIOB and output it to the global input/output line pair GIO, GIOB.

Meanwhile, although not shown in FIG. 19, the sense amplifier 1970 may further include a precharge unit. The precharge unit may equalize the voltage of the bit line BL and the complementary bit line BLB to the precharge voltage before and after the operation of the N-type sense amplifier 1971 or the P-type sense amplifier 1973.

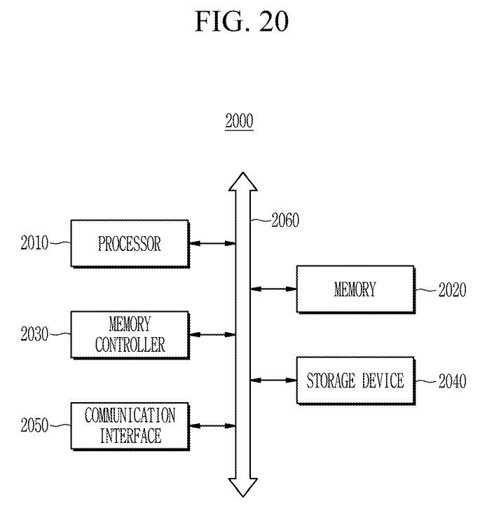

FIG. 20 is a block diagram illustrating a computing device according to one embodiment of the present disclosure.

Referring to FIG. 20, a computing device 2000 includes a processor 2010, a memory 2020, a memory controller 2030, a storage device 2040, a communication interface 2050, and a bus 2060. The computing device 2000 may further include other general-purpose components.

The processor 2010 controls the overall operation of each component of the computing device 2000. The processor 2010 may be implemented with at least one of various processing units, such as a central processing unit (CPU), an application processor (AP), and a graphic processing unit (GPU).

Memory 2020 stores various data and commands. The memory 2020 may be implemented as a memory device described with reference to FIGS. 1 to 19. Specifically, the memory 2020 may include a bit line and complementary bit line connection structure that allows coupling occurring between bit lines and between complementary bit lines to be self-cancelled, as illustrated in FIGS. 1 to 19, and may connect a memory region and a peripheral circuit region without signal disconnection through additional bonding pads and metal wiring.

The memory controller 2030 controls the transfer of data or commands to and from the memory 2020. In some embodiments, the memory controller 2030 may be provided as a separate chip from the processor 2010. In some embodiments, the memory controller 2030 may be provided as an internal component of the processor 2010.

The storage device 2040 non-temporarily stores programs and data. In some embodiments, the storage device 2040 may be implemented as non-volatile memory.

The communication interface 2050 supports wired and wireless Internet communication of the computing device 2000. Additionally, the communication interface 2050 may support various communication methods other than Internet communication.

The bus 2060 provides communication between components of the computing device 2000. The bus 2060 may include at least one type of bus depending on the communication protocol between the components.

Although the embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A memory device, comprising:
a plurality of memory cell arrays including a plurality of bit lines extending in a first direction, and a plurality of complementary bit lines extending in the first direction and corresponding to the plurality of bit lines; and
a bit line sense amplifier array arranged on the plurality of memory cell arrays in a second direction intersecting the first direction, overlapped at least partly with the plurality of memory cell arrays, and connected to a subset of bit lines included in the plurality of bit lines through a cell wafer metal wiring connected to the subset of the bit lines, and connected to a subset of complementary bit lines included in the plurality of complementary bit lines through a cell wafer metal wiring connected to the subset of the complementary bit lines.

2. The memory device of claim 1, wherein:
the plurality of memory cell arrays include first through fourth memory cell arrays,
the first memory cell array and the second memory cell array include a first bit line extending in the first direction, and
the third memory cell array and the fourth memory cell array include a first complementary bit line extending in the first direction and corresponding to the first bit line.

3. The memory device of claim 2, wherein:
the first bit line included in the first memory cell array and the second memory cell array, and the first complementary bit line included in the third memory cell array and the fourth memory cell array, are each connected to corresponding cell wafer metal wiring through a contact formed in the second direction, and
the cell wafer metal wiring connected to the first bit line and the cell wafer metal wiring connected to the first complementary bit line are arranged above the first bit line and the first complementary bit line in the second direction.

4. The memory device of claim 3, wherein:
the cell wafer metal wiring connected to the first bit line included in the first memory cell array and the second memory cell array, and the cell wafer metal wiring connected to the first complementary bit line included in the third memory cell array and the fourth memory cell array, are connected to a first bit line sense amplifier among the bit line sense amplifier array through a bonding pad formed in the second direction.

5. The memory device of claim 4, wherein:
the first memory cell array and the fourth memory cell array further include a second bit line extending in the first direction, and
the second memory cell array and the third memory cell array further include a second complementary bit line extending in the first direction and corresponding to the second bit line.

6. The memory device of claim 5, wherein:
the first bit line and the second bit line included in the first memory cell array are arranged adjacently and spaced apart from each other in a third direction intersecting the first direction and the second direction,
the first bit line and the second complementary bit line included in the second memory cell array are arranged adjacently and spaced apart from each other in the third direction,
the first complementary bit line and the second complementary bit line included in the third memory cell array are arranged adjacently and spaced apart from each other in the third direction, and
the first complementary bit line and the second bit line included in the fourth memory cell array are arranged adjacently and spaced apart from each other in the third direction.

7. The memory device of claim 6, wherein:
the second bit line included in the first memory cell array, and the second complementary bit line included in the second memory cell array and the third memory cell array, are each connected to corresponding cell wafer metal wiring through a contact formed in the second direction, and
the cell wafer metal wiring connected to the second bit line and the cell wafer metal wiring connected to the second complementary bit line are arranged above the second bit line and the second complementary bit line, respectively, in the second direction.

8. The memory device of claim 7, wherein:
the cell wafer metal wiring connected to the second bit line included in the first memory cell array, and the cell wafer metal wiring connected to the second complementary bit line included in the second memory cell array and the third memory cell array, are connected to a second bit line sense amplifier among the bit line sense amplifier array through a bonding pad formed in the second direction.

9. The memory device of claim 7, wherein:
the cell wafer metal wiring connected to the second bit line included in the fourth memory cell array is connected to a peripheral wafer metal wiring connected to a second bit line sense amplifier among the bit line sense amplifier array through a jump pad formed in the second direction, and
the peripheral wafer metal wiring is arranged above the cell wafer metal wiring connected to the second bit line included in the fourth memory cell array in the second direction.

10. The memory device of claim 9, wherein:
the plurality of memory cell arrays and the cell wafer metal wiring are arranged on a first substrate, and
the bit line sense amplifier array and the peripheral wafer metal wiring are arranged on a second substrate arranged above the first substrate in the second direction.

11. The memory device of claim 1, wherein:
the plurality of memory cell arrays include first through third memory cell arrays,
the first memory cell array includes a first bit line extending in the first direction, and
the second memory cell array and the third memory cell array include a first complementary bit line extending in the first direction and corresponding to the first bit line.

12. The memory device of claim 11, wherein:
the first bit line included in the first memory cell array and the first complementary bit line included in the third memory cell array are each connected to corresponding cell wafer metal wiring through a contact formed in the second direction,
the cell wafer metal wiring connected to the first bit line and the cell wafer metal wiring connected to the first complementary bit line are arranged above the first bit line and the first complementary bit line, respectively, in the second direction.

13. The memory device of claim 12, wherein:
the cell wafer metal wiring connected to the first bit line included in the first memory cell array, and the cell wafer metal wiring connected to the first complementary bit line included in the third memory cell array, are connected to a first bit line sense amplifier among the bit line sense amplifier array through a bonding pad formed in the second direction.

14. The memory device of claim 13, wherein:
the first memory cell array and the second memory cell array further include a second bit line extending in the first direction, and
the third memory cell array further includes a second complementary bit line extending in the first direction and corresponding to the second bit line.

15. The memory device of claim 14, wherein:
the first bit line and the second bit line included in the first memory cell array are arranged adjacently and spaced apart from each other in a third direction intersecting the first direction and the second direction,
the first complementary bit line and the second bit line included in the second memory cell array are arranged adjacently and spaced apart from each other in the third direction, and
the first complementary bit line and the second complementary bit line included in the third memory cell array are arranged adjacently and spaced apart from each other in the third direction.

16. The memory device of claim 15, wherein:
the second bit line included in the first memory cell array, and the second complementary bit line included in the third memory cell array, are each connected to corresponding cell wafer metal wiring through a contact formed in the second direction, and
the cell wafer metal wiring connected to the second bit line and the cell wafer metal wiring connected to the second complementary bit line are arranged above the second bit line and the second complementary bit line, respectively, in the second direction.

17. The memory device of claim 16, wherein:
the cell wafer metal wiring connected to the second bit line included in the first memory cell array, and the cell wafer metal wiring connected to the second complementary bit line included in the third memory cell array, are connected to a second bit line sense amplifier among the bit line sense amplifier array through a bonding pad formed in the second direction.

18. A memory device comprising:
a first substrate including a plurality of bit lines extending in a first direction, a plurality of complementary bit lines extending in the first direction and corresponding to the plurality of bit lines, a plurality of cell wafer metal wirings formed above the plurality of bit lines and the plurality of complementary bit lines along a second direction intersecting the first direction and extending in the first direction, a plurality of contacts formed in the second direction and connecting a subset of bit lines included in the plurality of bit lines and a subset of complementary bit lines included in the plurality of complementary bit lines to the plurality of cell wafer metal wirings, and a plurality of bonding pads formed in the second direction and connected to the plurality of cell wafer metal wirings; and
a second substrate including a bit line sense amplifier array arranged above the first substrate along the second direction and connected to the plurality of bonding pads.

19. The memory device of claim 18, wherein:
the first substrate further includes a jump pad connecting a cell metal wiring connected to at least one bit line among the plurality of bit lines to the second substrate, and
the second substrate further comprises a peripheral wafer metal wiring connecting the jump pad to the bit line sense amplifier array.

20. A memory device comprising:
a plurality of first bit lines extending in a first direction;
a plurality of first complementary bit lines extending in the first direction and corresponding to the plurality of first bit lines;
a plurality of second bit lines extending in the first direction, and alternately arranged with the plurality of first bit lines or the plurality of first complementary bit lines along a second direction intersecting the first direction;
a plurality of second complementary bit lines extending in the first direction, and alternately arranged with the plurality of first bit lines or the plurality of first complementary bit lines along the second direction;
a plurality of cell wafer metal wirings arranged above the plurality of first bit lines, the plurality of first complementary bit lines, the plurality of second bit lines, and the plurality of second complementary bit lines along a third direction intersecting the first direction and the second direction, and connecting the plurality of first bit lines, the plurality of first complementary bit lines, the plurality of second bit lines, and the plurality of second complementary bit lines through a plurality of contacts; and
a plurality of bonding pads arranged above the plurality of cell wafer metal wirings along the third direction, and connecting the plurality of cell wafer metal wirings to a plurality of bit line sense amplifier arrays.
